(19) United States
(12) Patent Application Publication
(10) Pub. No.: US 2026/0333932 A1
(43) Pub. Date: Oct. 22, 2026

(54) APPARATUS FOR THE PRODUCTION OF PHOTOVOLTAIC STRINGS

(71) Applicant: ECOPROGETTI S.R.L., Carmignano Di Brenta (PD) (IT)

(72) Inventors: Domenico SARTORE, Carmignano Di Brenta (PD) (IT); Eugenio GONZATO, Carmignano Di Brenta (PD) (IT); Matteo MARINI, Carmignano Di Brenta (PD) (IT); Stefano MICCINI, Padova (IT)

(73) Assignee: ECOPROGETTI S.R.L., Carmignano Di Brenta (PD) (IT)

(21) Appl. No.: 19/468,697

(22) Filed: Feb. 3, 2026

(30) Foreign Application Priority Data
Mar. 5, 2025 (IT) 102025000004518

(51) Int. Cl. H10F 71/00; H10F 19/90

(52) U.S. Cl. CPC H10F 71/1375; H10F 19/90

(57) ABSTRACT

An apparatus for the production of photovoltaic strings defined by a plurality of photovoltaic cells arranged in series and on which relative conductive filaments for connection are arranged, comprising at least one transport member configured to transport, in an orderly manner, the photovoltaic cells and the conductive filaments towards a soldering device configured to solder the conductive filaments with respect to the photovoltaic cells, and at least one retaining member arranged in selective cooperation with the transport member and configured to at least temporarily retain the conductive filaments with respect to the photovoltaic cells, the retaining member comprising at least one stabilizing element configured to selectively cooperate with the transport member in such a way as to stabilize, at least temporarily, the mutual positioning between the retaining member and the transport member, and in such a way that the retaining member follows the movement defined by the transport member.

### FIELD OF THE INVENTION

The present invention concerns an apparatus used for the production of photovoltaic strings used in the production of solar panels. In particular, the apparatus according to the present invention is applied to consolidate, mechanically and electronically, a series of photovoltaic cells in order to increase the overall voltage of the system.

### BACKGROUND OF THE INVENTION

It is known, in the field of solar panel production, to produce series of photovoltaic cells mechanically and electronically connected to each other, in order to obtain desired photovoltaic strings.

Photovoltaic strings make it possible to increase the total voltage generated, by adding the individual voltages produced by each solar cell. In this way, it is possible to optimize the production of energy and ensure that the solar panel operates efficiently, allowing an effective electrical supply to the utilities, for example domestic or industrial, to which it is connected.

Apparatuses for the automated production of such photovoltaic strings are known, wherein the individual photovoltaic cells are positioned in order and aligned with each other, on a transport member, or transport belt. The latter retains the aligned photovoltaic cells below, for example by means of a vacuum system, and feeds them stepwise towards a soldering device, in which relative copper conductive wires, commonly called “ribbons”, are initially positioned to connect two consecutive cells, with a determined and precise distance, depending on the conductive screen printing of the cell.

The combination of the cells and their ribbons is fed stepwise from the conveyor belt towards a subsequent soldering head, where each ribbon is soldered on the cell, by means of the combination between a heat source, for example generated by UV lamps, and the pressure of a mechanical component that serves to keep the ribbons in their precise soldering positions with respect to the conductive screen printing of the cell.

Among the various known soldering heads there are, for example, those provided with a series of pins, which are constrained with respect to UV lamps. Through a vertical movement, the pins press the ribbon on the cell, while the lamps emit the desired amount of heat, allowing the cell and ribbon to join.

In the traditional soldering process it is not possible to guarantee with absolute certainty the alignment between ribbons and the corresponding conductive screen printing of the cell, in particular during the transition between the deposition of the ribbons on the cells and their actual soldering, since, in the upper part of the cell, the ribbons are only supported and do not have any system that constrains them in the relative movement with the cell. This drawback of the known systems mainly causes problems with soldering and with the electrical efficiency of the photovoltaic string, since to obtain an optimal mechanical and electronic connection the ribbons must correspond perfectly to the position of the screen printing of the cell.

Systems are also known that, in part, try to solve this problem, using retaining elements upstream of the soldering, for example using needles appropriately arranged according to the position of the ribbons and at least in part elastic, to apply a desired retention tension on the ribbons themselves.

However, even with these known solutions it has been found that, in particular during movement, the retaining elements can be subjected to accidental external lateral forces that prevent the desired pressure from being applied precisely and uniformly on each individual ribbon, being able to obtain an uneven and constant soldering effect over the entire length of the ribbon.

There is therefore the need to perfect a device for producing photovoltaic strings, that can overcome at least one of the disadvantages of the prior art.

To do this, it is necessary to solve the technical problem of ensuring the correct and effective soldering between ribbon and cell at the conductive screen printing of the latter.

In particular, one purpose of the present invention is to devise an apparatus for making strings of photovoltaic cells in which each ribbon can be maintained with stability and precision in its deposition position corresponding to the screen printing of the photovoltaic cell on which it is deposited.

Another purpose of the present invention is to realize an apparatus that is simple and economical to produce, and that makes it possible to substantially maintain the production and design geometries of the current apparatuses.

The Applicant has devised, tested and embodied the present invention to overcome the shortcomings of the state of the art and to obtain these and other purposes and advantages.

### SUMMARY OF THE INVENTION

The present invention is set forth and characterized in the independent claim. The dependent claims describe other characteristics of the present invention or variants to the main inventive idea.

In accordance with the above purposes and to resolve the technical problem in a novel and original way, also achieving considerable advantages compared to the state of the prior art, an apparatus according to the present invention is applied for the production of photovoltaic strings, of the type defined by a plurality of photovoltaic cells arranged in series with each other and on which relative conductive filaments, or ribbons, for connection are arranged, at the intended conductive serigraphs of the photovoltaic cells themselves, to define a mechanical and electronic connection between the latter, for the purpose of optimizing the generation of electrical power for solar panels.

The apparatus according to the present invention substantially comprises at least one transport member, for example a belt, which is configured to transport the photovoltaic cells and the relative conductive filaments in an orderly manner towards a soldering device, also forming part of the apparatus according to the present invention. The soldering device is configured to solder the conductive filaments with respect to the photovoltaic cells, so as to consolidate the mechanical and electronic connection of the photovoltaic cells and thus generate a photovoltaic string.

The apparatus according to the present invention comprises at least one retaining member, which is arranged in selective cooperation with the transport member and is configured to retain, at least temporarily, the conductive filaments in their intended soldering position with respect to the photovoltaic cells.

In accordance with one aspect of the present invention, the retaining member comprises at least one stabilizing element, which is configured to selectively cooperate with the transport member in order to both stabilize, at least temporarily, the mutual positioning between the retaining member and the transport member, and to ensure that the retaining member follows the movement of the transport member, at least until the soldering device is reached.

In this way, a firm and stable reciprocal and operational positioning between the retaining member and the transport member is defined, thus guaranteeing that the position of the conductive filaments is maintained with respect to the conductive serigraphs of the photovoltaic cells, essentially from their deposition on the photovoltaic cells until they are soldered together.

With the solution according to the present invention, correct and effective soldering between ribbon and cell is thus guaranteed at the conductive screen printing of the latter.

In addition, since the action of the stabilizing element takes place directly on the transport member, no modifications of the latter are required, or if modifications are required, they are minor. Therefore, the solution according to the present invention is simple and economical to implement.

A further advantage conferred by the solution according to the present invention is given by the fact that the retaining member, as defined by the present solution, makes it possible to keep the metal filaments in the correct and original position even at the soldering device, being able to provide for a simplification of the latter to the heat emission member only.

In accordance with another aspect of the present invention, the stabilizing element comprises at least one non-slip portion, for example a high friction coefficient pad, which is configured to cooperate by friction with the transport member, implementing the stabilization action and following the reciprocal movement between the retaining member and the transport member.

In accordance with another aspect of the present invention, the stabilizing element comprises at least one magnetic portion, for example a magnet, which is configured to cooperate by magnetic attraction with the transport member, for example provided with a relative metal bar, implementing the stabilization action following the reciprocal movement between the retaining member and the transport member.

According to one variant, the stabilizing element can comprise at least one mechanical portion, for example a pin, an elastic clamp or other, configured to cooperate by mechanical coupling with the transport member, for example provided with a relative housing seat, a dowel or other, implementing the stabilization action following the reciprocal movement between the retaining member and the transport member.

In accordance with some preferred embodiments of the present invention, the retaining member comprises a support frame, which in turn comprises at least one retaining portion, for example provided in a substantially central position, and at least one stabilizing portion, advantageously two opposite to the sides of the retaining portion, on which the stabilizing element is provided. With regard to the latter, there can be either one or more than one, or there can be a combination of different solutions, for example in the form of a non-slip portion, a magnetic or mechanical portion, or others, depending on the different stabilization conditions to be obtained.

In accordance with a further aspect of the present invention, the retention portion can comprise a plurality of pressure actuators, which are advantageously arranged in a grid with a conformation coordinated to the arrangement of the conductive filaments with respect to the photovoltaic cells, and are configured to apply a certain retention pressure on the conductive filaments, at least temporarily.

In accordance with some embodiments of the solution according to the present invention, each of the pressure actuators comprises at least one pressure head configured to directly cooperate with the conductive filaments, and at least one elastic member, interposed between the pressure head and the support frame, which elastic member is configured to exert a desired elastic pressure on the pressure head.

In accordance with a further aspect of the present invention, the apparatus comprises a plurality of retaining members, which are arranged in series with each other, each one for retaining, at least temporarily, corresponding conductive filaments with respect to relative photovoltaic cells.

### DESCRIPTION OF THE DRAWINGS

These and other aspects, characteristics and advantages of the present invention will become apparent from the following description of some embodiments, given as a non-restrictive example with reference to the attached drawings wherein:

FIG. 1 schematically shows an apparatus for the production of photovoltaic strings according to the present invention;

FIG. 2 schematically shows a detail of the apparatus of FIG. 1;

FIG. 3 schematically shows a sectional view of the detail of FIG. 2;

FIG. 4 schematically shows a bottom view of a component of the apparatus of FIG. 1;

FIG. 5 schematically shows a detail in partial section of the component of FIG. 4;

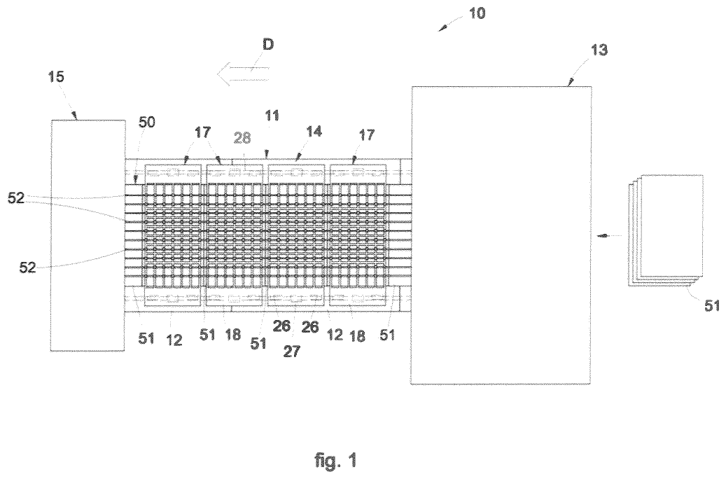

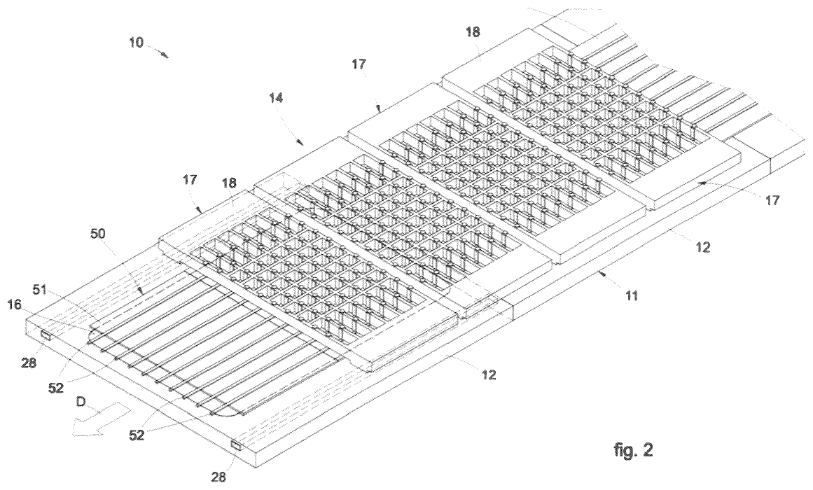

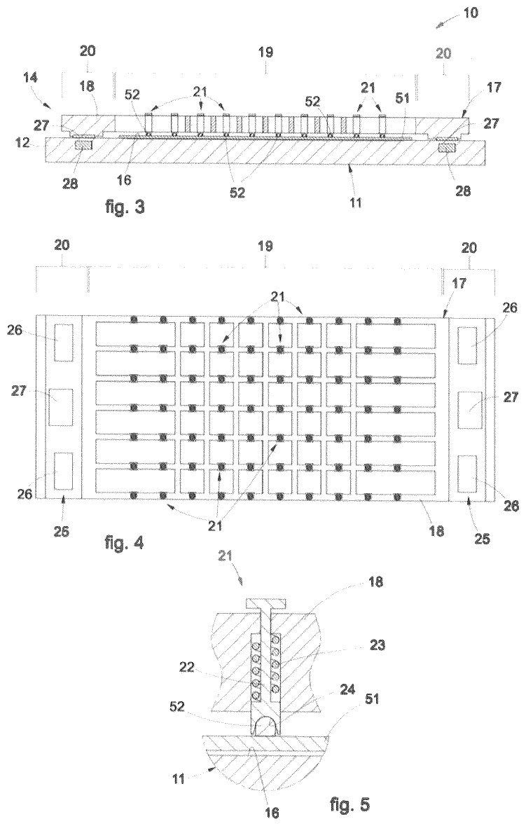

We must clarify that in the present description the phraseology and terminology used, as well as the figures in the attached drawings also as described, have the sole function of better illustrating and explaining the present invention, their function being to provide a non-limiting example of the invention itself, since the scope of protection is defined by the claims.

To facilitate comprehension, the same reference numbers have been used, where possible, to identify identical common elements in the drawings. It is understood that elements and characteristics of one embodiment can be conveniently combined or incorporated into other embodiments without further clarifications.

### DESCRIPTION OF SOME EMBODIMENTS OF THE PRESENT INVENTION

With reference to the attached figures, an apparatus 10 according to the present invention is applied for the production of photovoltaic strings 50, only schematically shown, which are commonly defined by a plurality of photovoltaic cells 51 arranged in series with each other and on which relative conductive filaments, or ribbons 52, are arranged for connection, at the expected conductive serigraphs of the photovoltaic cells 51 themselves. The ribbons 52 thus arranged and, as will be shown, subsequently soldered to the photovoltaic cells 51, define a mechanical and electronic connection between the latter, so as to optimize the generation of electrical energy for the solar panels, of a substantially known type and not illustrated in the attached figures.

The apparatus 10 according to the present invention substantially comprises a transport member, or belt 11, for example of the type defined by a plurality of sections 12 hinged together, and configured to transport the series of photovoltaic cells 51 and the related ribbons 52 in an orderly manner along a transport direction D.

In the solution outlined in the attached figures, each section 12 comprises a pneumatically operated constraint area 16, which is operatively located in cooperation with a lower surface of the photovoltaic cells 51, so as to retain them by depression at least along the direction of transport D.

A deposition device 13, a retaining member 14 and a soldering device 15 are also part of the apparatus 10 according to the present invention, in sequence according to the direction of transport D.

The deposition device 13 and the soldering device 15 are of substantially traditional type. The deposition device 13 is configured to accurately deposit the ribbons 52 on the photovoltaic cells 51 at the expected conductive serigraphs of the photovoltaic cells 51 themselves. The soldering device 15 is configured to solder the ribbons 52 with respect to the photovoltaic cells 51, so as to consolidate the mechanical and electronic connection between the photovoltaic cells 51 and thus generate the photovoltaic string 50.

According to the present invention, the retaining member 14 is arranged in selective cooperation with the belt 11 and is configured to retain, at least temporarily, the ribbons 52 deposited by the deposition member 13 in their intended soldering position with respect to the photovoltaic cells 51, at least in the transport section along the transport direction D, which goes from the deposition device 13 to the soldering device 15.

In particular, the retaining member 14 comprises a plurality of retaining members 17 also arranged in sequence along the transport direction D, and each of which comprises a support frame 18.

The support frame 18 comprises, in turn, at least one retaining portion 19, provided in a substantially central position, and two stabilizing portions 20, opposite the sides of the retaining portion 19. In other words, in an operating condition the retaining portion 19 comes to be located substantially above the photovoltaic cells 51 and the relative ribbons 52, while the two retaining portions 20 come to be located above corresponding lateral portions of the sections 12 of the belt 11.

The retaining portion 19 comprises a plurality of pressure actuators 21 arranged in a grid with a conformation coordinated to the arrangement of the ribbons 52, with respect to the photovoltaic cells 51, and configured to apply a certain retention pressure on said ribbons 52.

With particular reference to FIG. 5, each pressure actuator 21 comprises at least one pressure head 22 configured to cooperate directly with the ribbons 52, and at least one elastic member, or spring 23, operatively interposed between the pressure head 22 and the support frame 18, so as to exert a desired elastic pressure on the pressure head 22 and, indirectly, on the ribbon 52.

Advantageously, the pressure head 22 has an end 24, shaped in a manner coordinated to the transverse conformation of the ribbon 52, so as to ensure an optimal distribution of the pressure exerted.

On each stabilizing portion 20, and in particular at a surface facing, in use, the belt 11, different stabilizing elements 25 are provided, which are configured to selectively cooperate with the belt 11, both so as to stabilize, at least temporarily, the mutual positioning between each retaining member 17 and the sections 12 of the belt 11, and so that the retaining member 17 follows the movement of the belt 11, substantially without relative movements, along the transport direction D, at least up to the soldering device 15.

In the embodiment outlined in the attached figures, the stabilization elements 25 comprise, for each stabilization portion 20, two non-slip portions 26, for example two rubber pads or other high friction coefficient material, which cooperate directly by friction with the corresponding sections 12 of the belt 11, implementing the stabilization action following the reciprocal movement between the retaining member 17 and the belt 11.

Advantageously, each non-slip portion 26 has a coefficient of friction between about 0.03 and about 0.5, so that, together with the operating pressure of the support frame 18, a certain frictional force is guaranteed, the latter sufficient to guarantee an effective stability of the relative position between the support frame 18 and the corresponding section 12.

Still in the embodiment schematically shown in the attached figures, the stabilizing elements 25 comprise, for each stabilizing portion 20, also a magnetic portion 27, for example a magnet, which cooperates by magnetic attraction with the corresponding section 12 of the belt 11. In this solution, to emphasize the magnetic effect and allow a free choice for the production of the sections 12, understood as the choice of the material for production, each section 12 is provided with relative metal bars 28, arranged longitudinally and at the magnetic portions 27, in order to guarantee a desired magnetic attraction force, sufficient to guarantee an effective stabilization action following the reciprocal movement between the retaining member 17 and the belt 11.

Although in the embodiment shown in the attached figures friction or magnetic stabilizing elements 25 are schematically shown, equally effective alternative solutions for stabilization following the reciprocal movement between the retaining member 17 and the belt 11 are not excluded. For example, according to a variant not shown, the stabilizing element 25 may comprise at least one mechanical portion, for example a pin, an elastic clamp or other, configured to cooperate by mechanical coupling with the transport member 17, for example provided with a relative housing seat, a dowel or other, obtained on the corresponding sections 12 of the belt 11.

It is clear that modifications and/or additions of parts may be made to the apparatus 10 disclosed herein, without departing from the scope of the present invention as defined by the claims.

It is also clear that, although the present invention has been described with reference to some specific examples, a person of skill in the art shall certainly be able to achieve other equivalent forms of apparatus for the production of photovoltaic strings having the characteristics as set forth in the claims and hence all coming within the field of protection defined thereby.

In the following claims, the sole purpose of the references in brackets is to facilitate their reading and they must not be considered as restrictive factors with regard to the field of protection defined by the claims.

1. An apparatus for the production of photovoltaic strings defined by a plurality of photovoltaic cells arranged in series and on which relative conductive filaments for connection are arranged, comprising at least one transport member configured to transport, in an orderly manner, said photovoltaic cells and said conductive filaments towards a soldering device configured to solder said conductive filaments with respect to said photovoltaic cells, and at least one retaining member arranged in selective cooperation with said transport member and configured to at least temporarily retain said conductive filaments with respect to said photovoltaic cells, wherein said at least one retaining member comprises at least one stabilizing element configured to selectively cooperate with said transport member so as to stabilize, at least temporarily, the mutual positioning between said retaining member and said transport member, or so that said retaining member follows the movement defined by said transport member.

2. The apparatus as in claim 1, wherein said stabilizing element comprises at least one non-slip portion configured to cooperate by friction with said transport member and follow its movement.

3. The apparatus as in claim 1, wherein said stabilizing element comprises at least one magnetic portion configured to cooperate by magnetic attraction with said transport member and follow its movement.

4. The apparatus as in claim 1, wherein said stabilizing element comprises at least one mechanical portion configured to cooperate for mechanical coupling with said transport member and follow its movement.

5. The apparatus as in claim 1, wherein said at least one retaining member comprises a support frame having at least one retaining portion and at least one stabilizing portion on which said at least one stabilizing element is provided.

6. The apparatus as in claim 5, wherein said retaining portion comprises a plurality of pressure actuators arranged in a grid with a conformation coordinated to the arrangement of said conductive filaments with respect to said photovoltaic cells, and configured to apply a certain retaining pressure on said conductive filaments.

7. The apparatus as in claim 6, wherein each of said pressure actuators comprises at least one pressure head configured to directly cooperate with said conductive filaments, and at least one elastic member interposed between said pressure head and said support frame and configured to exert a desired elastic pressure on said pressure head.

8. The apparatus as in claim 5, wherein said support frame comprises a central retaining portion and two stabilizing portions obtained laterally and on parts opposite to said retaining portion.

9. The apparatus as in claim 5, wherein at least two non-slip portions and at least one magnetic cooperation portion are provided on each stabilizing portion.

10. The apparatus as in claim 1, wherein the apparatus comprises a plurality of retaining members arranged in series with each other, each one for retaining, at least temporarily, corresponding conductive filaments with respect to said relative photovoltaic cells.
